(19) United States
(12) Patent Application Publication
(10) Pub. No.: US 2012/0145988 A1
(43) Pub. Date: Jun. 14, 2012

(54) Nanoscale Apparatus and Sensor With Nanoshell and Method of Making Same

(76) Inventors: Nathaniel J. Quitoriano, Pacifica, CA (US); Theodore I. Kamins, Palo Alto, CA (US)

(21) Appl. No.: 13/146,880

(22) PCT Filed: Jan. 29, 2009
(86) PCT No.: PCT/US2009/032498

§ 371 Date: Jul. 28, 2011

(51) Int. Cl. H01L 29/06; H01L 21/20; B82Y 99/00; B82Y 40/00

(52) U.S. Cl. 257/9; 438/478; 257/E29.024; 257/E21.09; 977/762

(57) ABSTRACT

A nanoscale apparatus (100) includes a nanoshell (110) extending from a substrate (102) and an epitaxial connection (120) between the substrate and an end (112) of the nanoshell adjacent to the substrate. A nanoscale sensor (200) includes surfaces (204, 206) extending relatively perpendicular to each other, a nanoshell (210) extending from one of the surfaces, and a detector (220) that monitors motion of the nanoshell relative to another of the surfaces spaced from the nanoshell by a gap (208). A method (300) of making a nanoscale apparatus includes growing (310) a nanowire on a surface; forming (320) a core-shell composite nanostructure; exposing (330) an end of the nanowire opposite to the surface with a FIB; and removing (340) the nanowire core from the exposed end, such that a nanoshell having a hollow region is attached to the surface. A material of the nanoshell (110, 210) excludes sp²-bonded carbon materials.

### CROSS-REFERENCE TO RELATED APPLICATIONS

N/A

### STATEMENT REGARDING FEDERALLY SPONSORED RESEARCH OR DEVELOPMENT

N/A

### BACKGROUND

A consistent trend in semiconductor technology since its inception is toward smaller and smaller device dimensions and higher and higher device densities. As a result, an area of semiconductor technology that recently has seen explosive growth and generated considerable interest is nanotechnology. Nanotechnology is concerned with the fabrication and application of so-called nanoscale structures, structures having at least one linear dimension between 1 nm and 200 nm. These nanoscale structures are often 5 to 100 times smaller than conventional semiconductor structures.

A nanowire is nanoscale, crystalline structure typically characterized as having two dimensions or directions that are much less than a third dimension. Typically, the third or major dimension of a nanowire is its length along a longitudinal axis of a nanowire. The axial length is relatively much larger than a width or a depth of the nanowire. Nanowires characteristically have a solid core, such that a mass of a nanowire is much greater than the mass of a nanoscale structure with a similar diameter and a hollow core, i.e., a nanotube.

A carbon nanotube is a cylindrical, hollow nanoscale structure having a length much greater than its diameter. Carbon nanotubes have unique properties such that they find use in many applications, such as electrical, optical, thermal and structural applications. However, techniques are needed to handle carbon nanotubes and to attach carbon nanotubes to structures for use in the applications in which they find use.

### BRIEF DESCRIPTION OF THE DRAWINGS

The various features of embodiments of the present invention may be more readily understood with reference to the following detailed description taken in conjunction with the accompanying drawings, where like reference numerals designate like structural elements, and in which:

FIG. 1A illustrates a side view of a nanoscale apparatus according to an embodiment of the present invention.

FIG. 1B illustrates a side view of a nanoscale apparatus according to another embodiment of the present invention.

FIG. 2A illustrates a magnified cross sectional view of a nanoscale apparatus having a direct epitaxial connection according to an embodiment of the present invention.

FIG. 2B illustrates a magnified cross sectional view of a nanoscale apparatus having an indirect epitaxial connection according to another embodiment of the present invention.

FIG. 3A illustrates a side view of a portion of a nanoscale sensor according to an embodiment of the present invention.

FIG. 3B illustrates a side view of a portion of a nanoscale sensor according to another embodiment of the present invention.

FIG. 4 illustrates a flow chart of a method of making a nanoscale apparatus according to an embodiment of the present invention.

### DETAILED DESCRIPTION

According to various embodiments of the present invention, a nanoscale apparatus and a nanoscale sensor employ a nanoshell formed in place attached to a surface of a substrate. In some embodiments, the substrate is a crystalline substrate with a crystalline substrate surface. In other embodiments, the substrate is an amorphous substrate with a layer of a crystalline material on the substrate surface. In either of these embodiments, the nanoshell is attached to the crystalline substrate surface. In still other embodiments, the substrate and the substrate surface are amorphous and the nanoshell is attached to the amorphous substrate surface.

In some embodiments, the attachment between the nanoshell and the substrate is an epitaxial connection, which may be a direct epitaxial connection or an indirect epitaxial connection, depending on the embodiment. An epitaxial connection provides for the nanoshell to be ultimately anchored to the substrate with integral and strong bonds. Moreover, the epitaxial connection reduces clamping loss that is found when other methods of connection are used. Clamping loss may be particularly problematic in systems that use mechanically resonant structures. In other embodiments, the attachment between the nanoshell and the substrate is a non-epitaxial connection having strong bonds.

In a direct epitaxial connection between the nanoshell and the substrate, an end of the nanoshell physically or directly epitaxially connects to the substrate surface, and both the nanoshell and the substrate surface independently comprise a crystalline material that share a crystallographic relationship at the connection. In an indirect epitaxial connection, a nanowire stub provides the epitaxial connection between the nanoshell and the substrate. A ‘nanowire stub’ is a portion of a single crystal nanowire connected at one end to the substrate and connected at an opposite end to the nanoshell. In some embodiments of the indirect epitaxial connection, one of the connections of the nanowire stub to either the nanoshell or the substrate is a direct epitaxial connection while the other connection is non-epitaxial. In other embodiments of the indirect epitaxial connection, both connections of the nanowire stub to the nanoshell and the substrate are direct epitaxial connections. In some embodiments of the indirect epitaxial connection, an end of the nanoshell is spaced from the substrate surface.

The nanoscale apparatus finds use in different applications including but not limited to, a mechanical resonant sensor. For example, the nanoscale apparatus may be used as a sensor for one or more target species, such as gas species, chemical species and biological species. A resonant frequency of the nanoshell changes as the mass of the nanoshell is changed due to an interaction between the target species and the nanoshell. As such, the lower mass of the nanoshell makes for a better mechanically resonant structure than a nanowire of similar diameter.

In some embodiments of the nanoscale sensor, the substrate has relatively perpendicular extending surfaces. For example, a post or a wall may extend relatively vertically from a horizontal surface of the substrate. The nanoshell functions as a mechanically resonant structure that extends from one of the substrate surfaces while the other of the substrate surfaces is adjacent to and spaced from the nanoshell by a gap. In some embodiments, opposite ends of the nanoshell are connected to opposing walls that extend from the relatively horizontal surface of the substrate. The nanoscale sensor further employs means for detecting movement of the nanoshell relative to the other surface. In some embodiments, the means for detecting comprises a detector and one or both of the surfaces may comprise an electrode. When the nanoshell is epitaxially connected to one of the surfaces of the substrate, the nanoscale sensor realizes reduced clamping loss.

The nanoscale apparatus may be fabricated using a bottom-up fabrication approach. A method of making the nanoscale apparatus according to various embodiments of the present invention employs a nanowire grown on the substrate as a sacrificial template for the formation of the nanoshell. A core-shell composite nanostructure is formed using the nanowire as a core. Most or all of the length of the nanowire core is subsequently removed from the core-shell composite nanostructure, depending on the embodiment. A resultant nanostructure is the nanoshell with a hollow region. The nanoshell has a wall that is very thin compared to the length of the nanoshell. Certain embodiments of the present invention have other features that are one or both of in addition to and in lieu of the features described herein. These and other features of some embodiments of the invention are detailed below with reference to the drawings.

As used herein, a ‘nanoshell’ is defined as a hollow nanoscale structure having opposite ends, an axial length along a longitudinal axis of the nanoshell as a major dimension and a ‘diameter’ of the nanoshell as a relatively minor dimension. In contrast, a nanowire is a solid nanoscale structure and by definition, has a greater mass than a nanoshell of the same diameter. The nanoshell may be considered to be approximately cylindrical in shape in that by definition, a lateral cross section of the nanoshell, which is perpendicular to the longitudinal axis, has one of a circular shape, an elliptical shape, and a polygonal shape, according to the various embodiments herein. Moreover, the shape of an inner lateral cross section and an outer lateral cross section of the nanoshell may be different. Use of the term ‘diameter’ with respect to the nanoshell or the nanowire is intended to mean a distance across the lateral cross section, regardless of the lateral cross sectional shape. Depending on the embodiment, the nanoshell may be either crystalline or amorphous.

Moreover, the nanoshell is mechanically rigid compared to a nanowire of similar length and mass, such that further processing of the nanoshell may be achieved without breaking the nanoshell. Moreover, a larger diameter and a larger surface area of a nanoshell relative to a similar length nanowire of the same mass may increase the signal to noise ratio of some resonance measuring techniques. As a resonant structure, resonant frequency detection by some methods is easier compared to a nanowire of similar mass. Nanoshells also have other properties not observed in nanowires. For example, nanoshells are less likely to adhere to adjacent nanoshells during processing compared to nanowires of similar mass.

The nanoshell further has very different properties and characteristics than a carbon nanotube. A ‘carbon nanotube’ is defined herein as a nanotube whose carbon-carbon bonds are predominantly sp² bonds. The ‘nanoshell’ of the various embodiments herein does not comprise any carbon-carbon sp² bonds. Hence, the term ‘nanoshell’ is further defined here as being is synonymous with a nanoshell material that excludes sp² carbon-carbon bonds or excludes sp²-bonded carbon materials. For simplicity of discussion, the term ‘nanoshell’ is used herein to specifically exclude sp²-bonded carbon materials. As such, a carbon nanotube is not interchangeable with the nanoshell according to the various embodiments of the present invention herein. For example, a carbon nanotube does not have a three-dimensional (3-D) crystal structure, as defined herein. Also, a carbon nanotube can not form the same type of isoepitaxial connection to commonly available crystalline surfaces that the nanoshell can, in accordance with some embodiments herein.

The term ‘crystalline’, as used herein, means a material having a three-dimensional (3-D) crystalline lattice. One or more of the nanoshell, the surface to which the nanoshell is connected, and the substrate may be a crystalline material, as defined herein, depending on the embodiment. In contrast, a carbon nanotube, as defined herein, has a two-dimensional (2-D) crystal structure that wraps around a central axis and joins to form a structure with a cylindrical surface. The term ‘crystalline’ is intended to include within its scope a single crystal material, a polycrystalline material and a microcrystalline material. An amorphous material is distinguished from a crystalline material herein as having relatively no crystal structure. A crystalline material may form an epitaxial connection with another crystalline material while an amorphous material can not. In some embodiments, one or both of the nanoshell and the surface to which the nanoshell is connected comprises a single crystal material. Moreover, in the embodiments that comprise a nanowire stub, the nanowire stub is a single crystal material.

The term ‘substrate’, as defined herein means a structure that supports and is connected to the nanoshell. The surface of the substrate may be different from a base of the substrate. By ‘different’ it is meant that the surface may be a different material than the base; or the surface may have a different structure from the base (e.g., a crystalline silicon surface and an amorphous silicon base; or single crystal silicon surface versus a polycrystalline silicon base). As mentioned above, the substrate may be either crystalline or amorphous. Either the crystalline substrate or the amorphous substrate may comprise a crystalline surface layer on the substrate, depending on the embodiment. For example, an amorphous substrate may comprise a crystalline surface layer or the amorphous substrate may be amorphous at the surface of the substrate. In another example, a polycrystalline substrate may comprise a single crystal surface layer or the polycrystalline substrate may be polycrystalline at the surface of the substrate. No distinction is made herein between the substrate and the substrate surface unless a distinction is necessary. Therefore, reference to a ‘crystalline surface of a substrate,’ according to some embodiments herein, is intended to include within its scope a substrate base that may or may not be different from the crystalline substrate surface.

The term ‘epitaxial connection’ or ‘epitaxially connected’, as used herein, is defined as a connection between structures in which a crystal lattice of a structure being formed has a 3-D crystallographic or orientation relationship to a crystal lattice of a template on which the structure is formed. The term ‘epitaxial connection’ or ‘epitaxially connected’, as used herein, includes within its scope a direct epitaxial connection between the nanoshell and the substrate (or a surface thereof) and an indirect epitaxial connection between a nanoshell and a substrate (or a surface thereof). The term ‘epitaxial connection’ or ‘epitaxially connected’ is a structural limitation and is not intended as a process limitation herein. An epitaxial connection reduces clamping losses in mechanically resonant structures at least due to the many and strong bonds formed between the resonant structure and the substrate.

The substrate, the nanoshell and according to some embodiments of the present invention, the nanowire (e.g., the nanowire stub), may be a semiconductor material each independently selected from a semiconductor or a compound semiconductor composed of Group IV elements (e.g., Si, Ge, SiGe), a compound semiconductor composed of elements from Group III and Group V (e.g., GaAs, InGaAs), and a compound semiconductor composed of elements from Group II and Group VI (e.g., ZnO, CdS). Moreover, the nanoshell material may include diamond for example, but excludes graphite, because by definition, the nanoshell does not include sp² bonded carbon atoms, as provided above. As described further below with respect to a method of fabrication that includes formation of a core-shell composite nanostructure, the material of the nanowire and the material of the nanoshell are chemically different such that the material of the nanowire may be selectively removed from the core-shell composite nanostructure, such as by chemical etching, to leave a hollow region surrounded by the material of the nanoshell.

In some embodiments, one or both of the substrate and the nanoshell independently comprises an oxide, sulfide, or a nitride of a metal or a semiconductor. Moreover, the substrate may further comprise a carbide of a metal or a semiconductor. For example, one or both of the substrate and the nanoshell may independently comprise an aluminum oxide (e.g., alumina Al₂O₃) component. In another example, one or both of the substrate and the nanoshell may independently comprise a silicon oxide (SiOₓ) component or a silicon nitride (Si_{y}N_{z}) component. Moreover, the substrate may comprise glass, stainless steel, or a metal foil, for example.

Further, as used herein, the article ‘a’ is intended to have its ordinary meaning in the patent arts, namely ‘one or more’. For example, ‘a nanoshell’ generally means one or more nanoshells and as such, ‘the nanoshell’ means ‘the nanoshell(s)’ herein. Also, any reference herein to ‘top’, ‘bottom’, ‘side’, ‘upper’, ‘lower’, ‘up’, ‘down’, ‘left’, ‘right’, ‘first’ or ‘second’ is not intended to be a limitation herein. Moreover, examples herein are intended to be illustrative only and are presented for discussion purposes and not by way of limitation.

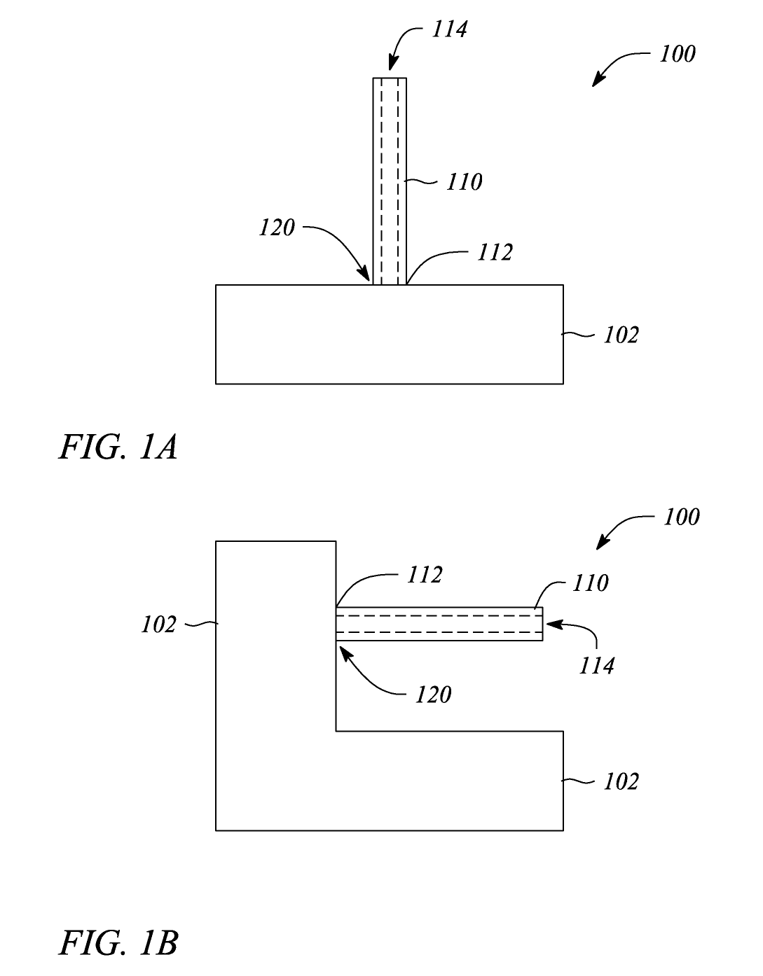

In some embodiments of the present invention, a nanoscale apparatus is provided. FIG. 1A illustrates a side view of a nanoscale apparatus 100 according to an embodiment of the present invention. FIG. 1B illustrates a side view of a nanoscale apparatus 100 according to another embodiment of the present invention. The nanoscale apparatus 100 comprises a nanoshell 110 extending from a substrate 102 and an epitaxial connection 120 between an end 112 of the nanoshell 110 and the substrate 102. The nanoshell 110 is defined above and has a hollow region 114 along the axial length of the nanoshell 110 (delineated with dashed lines in FIGS. 1A and 1B). In FIG. 1A, the nanoshell 110 extends relatively vertically from a horizontal plane of the substrate 102. In contrast, the nanoshell 110 extends relatively horizontally from a vertical plane of the substrate 102 that further comprises a horizontal plane in FIG. 1B. The nanoshell 110 in either FIG. 1A or 1B is ‘formed in place’ on the respective surface of the substrate 102. The term ‘formed in place’ means that the nanoshell 110 is formed concomitant with the epitaxial connection 120 to the substrate 102 and therefore, is not formed separately and then attached to the substrate 102. The direction that the nanoshell extends from the substrate depends in part on a crystal direction of the surface from which the nanoshell 110 is formed.

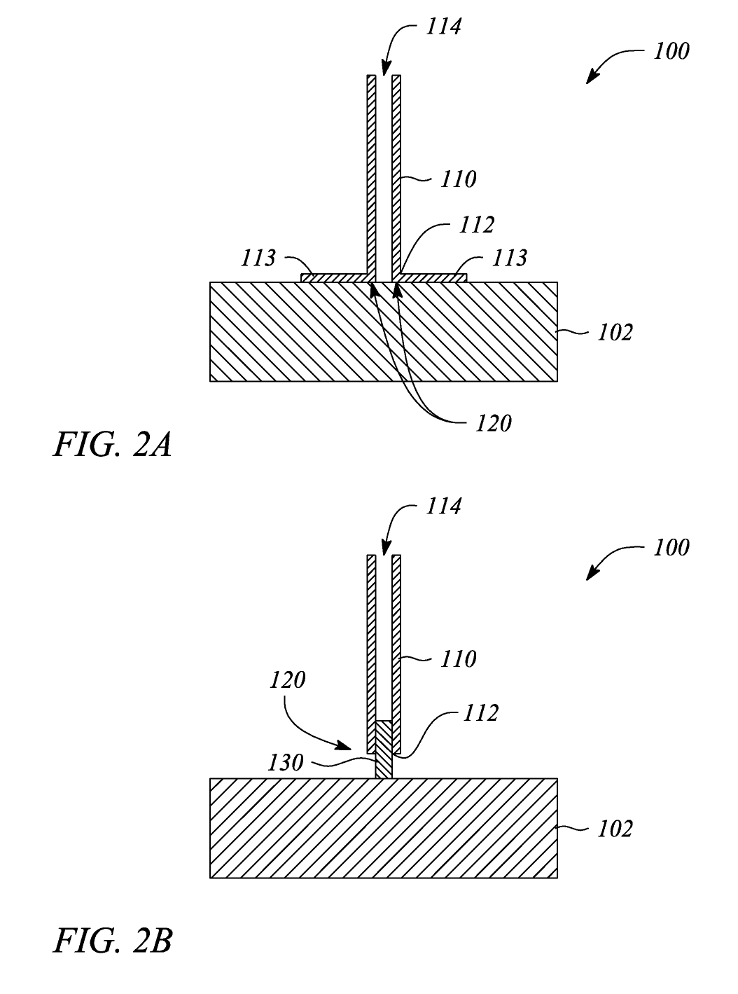

In some embodiments, the epitaxial connection 120 is a direct epitaxial connection between the nanoshell 110 and the substrate 102. In these embodiments, both the nanoshell 110 is a crystalline material and the substrate 102 comprises a crystalline material at a surface of the substrate 102 to facilitate the direct epitaxial connection 120. For example, the substrate 102 may be either a crystalline substrate or an amorphous substrate comprising a layer of a crystalline material on the substrate surface, as described above. According to these embodiments, the direct epitaxial connection 120 forms at an interface between the end 112 of the nanoshell 110 and the substrate surface. FIG. 2A illustrates a cross sectional magnified view of the nanoscale apparatus 100 wherein the nanoshell 110 has a direct epitaxial connection 120 to the substrate 102 according to an embodiment of the present invention. In some embodiments, the material of the nanoshell 110 also forms a crystalline base layer 113 on the crystalline surface of the substrate 102 that surrounds and is continuous with the end 112 of the nanoshell 110, as illustrated in FIG. 2A by way of example. The continuous crystalline base layer 113 of the nanoshell 110 also may be directly epitaxially connected to the crystalline surface of the substrate 102, according to some embodiments.

In other embodiments, the epitaxial connection 120 is an indirect epitaxial connection between the nanoshell 110 and the substrate 102 by way of a nanowire stub within a portion of the hollow region 114 of the nanoshell 110. FIG. 2B illustrates a cross sectional magnified view of the nanoscale apparatus 100 wherein the nanoshell 110 has an indirect epitaxial connection 120 to the substrate 102 according to an embodiment of the present invention. In these embodiments, one or both of the nanoshell 110 and the surface of the substrate 102 independently comprises a crystalline material. For example, the nanowire stub 130 may be directly epitaxially connected to a crystalline surface of the substrate 102 at one end and connected to the nanoshell 110 at an opposite end. In this example, the nanoshell 110 may be either crystalline or amorphous, such that the connection between the nanowire stub 130 and the nanoshell 110 is either epitaxial or non-epitaxial. In another example, the nanowire stub 130 may be directly epitaxially connected to a crystalline nanoshell 110 at one end and connected to the substrate 102 at an opposite end. In this example, one or both of the substrate and the substrate surface may be either crystalline or amorphous, such that the connection between the nanowire stub 130 and the substrate 102 is either epitaxial or non-epitaxial.

As illustrated in FIG. 2B, one end of the nanowire stub 130 is attached to the substrate and an opposite end of the nanowire stub 130 extends into the hollow region 114 of the nanoshell 110. The end 112 (or an axial end portion 112) of the nanoshell 110 overlaps an axial end portion of the nanowire stub 130 that is opposite to the substrate 102. In some embodiments, as illustrated in FIG. 2B, the end 112 of the nanoshell 110 is spaced from the substrate 102 surface, such that an axial base portion of the nanowire stub 130 is exposed. In other embodiments not illustrated herein, the axial base portion of the nanowire stub 130 is covered either by the nanoshell material or another material, such as an insulator material, for example.

The embodiments in FIGS. 2A and 2B are illustrative only. The nanoshell 110 of either embodiment in FIG. 2A or 2B may be laterally extending from a vertical portion of the substrate 102 as in FIG. 1B and still be within the scope of the embodiments herein. Moreover, the nanoshell of either embodiment may be attached at both ends between relatively parallel extending walls and suspended above the substrate. Moreover, a relatively perpendicular relationship is illustrated between the nanoshell 110 and the substrate 102. As mentioned above, the direction that the nanoshell 110 extends relative to the substrate 102 depends on a crystal orientation or direction of the substrate material.

In some embodiments, the nanoscale apparatus 100 may further comprise means for detecting movement of the nanoshell 110, not illustrated in FIG. 1A-1B or 2A-2B. As provided above, the nanoshell 110 is a mechanically resonant structure that has a resonant frequency which changes with changes in the mass of the nanoshell. In some embodiments, the means for detecting movement comprises a detector connected to monitor movement of the nanoshell, for example movement relative to a gap created between the nanoshell and the horizontal surface of the substrate 102 in FIG. 1B.

In some embodiments, the nanoshell 110 comprises a functionalized surface to interact with a stimulus. The functionalized surface may be one or both of the exterior surface and the interior surface of the nanoshell. For example, the stimulus may be a target chemical species, such as a toxin. In this example, the nanoshell 110 may be functionalized with a chemical moiety selected from a hydroxyl group (—OH), a carboxylic acid group (—COOH), and a sulfonic acid group (—SO₃H), for example, that interacts with the target species when in a vicinity of the functionalized nanoshell. The chemical moiety used depends on the target stimulus for detection using the nanoscale apparatus 100. A nanoshell with a bound target species will resonant at a different resonant frequency than a nanoshell without a bound target species due to a change in the mass. The change in resonant frequency is quantifiable.

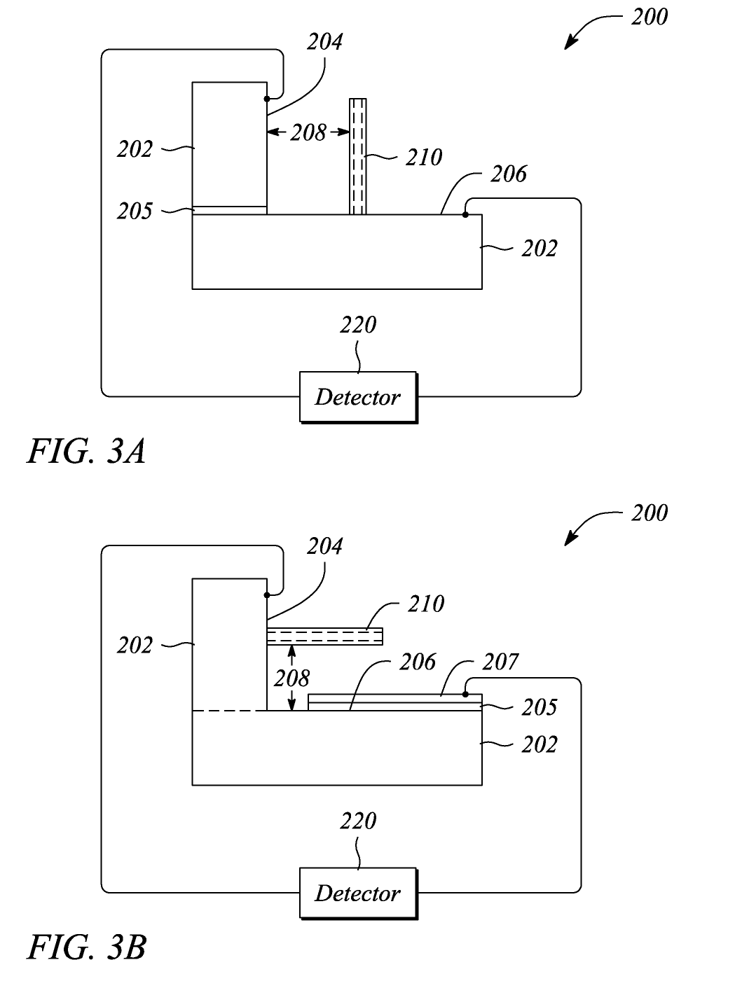

In some embodiments of the present invention, a nanoscale sensor is provided. FIGS. 3A and 3B illustrate side views of a portion of a nanoscale sensor 200 according to some embodiments of the present invention. The nanoscale sensor 200 comprises surfaces 204, 206 that extend relatively perpendicular to one another, such as a relatively vertical surface 204 and a relatively horizontal surface 206. The surfaces 204, 206 may be surfaces of a substrate 202 as illustrated in FIG. 3B, for example; or one of the surfaces 206 may be a surface of a substrate 202 while the other surface 204 is a surface of a wall or post on the substrate 202 as illustrated in FIG. 3A, for example. The nanoscale sensor 200 further comprises a nanoshell 210 extending from one of the surfaces 204, 206. In some embodiments, the nanoshell 210 extends relatively vertically from the horizontal surface 206 and is adjacent to and spaced from the vertical surface 204 by a gap 208, as illustrated in FIG. 3A. In other embodiments, the nanoshell 210 extends relatively horizontally from the vertical surface 204 and is adjacent to and spaced from the horizontal surface 206 by the gap 208, as illustrated in FIG. 3B. For simplicity of discussion the respective surface 204, 206 that is spaced from the nanoshell 210 by the gap 208 is referred to as the ‘opposing surface’ 204, 206, in that the respective surface 204, 206 is opposite to the nanoshell 210. The nanoshell 210 may be a mechanically resonant structure for a nanoscale resonant sensor, according to some embodiments.

The nanoscale sensor 200 further comprises means for detecting motion of the nanoshell 210 relative to the respective opposing surface 204, 206, depending on the embodiment. The means for detecting motion of the nanoshell 210 comprises a detector 220 that senses or monitors motion of the nanoshell 210. In some embodiments, the detector 220 may sense or monitor motion of the nanoshell 210 one of capacitively, electromagnetically and optically.

In some embodiments, the means for detecting motion further comprises an electrode connected to the nanoshell 210 and an electrode in or adjacent to the gap 208 on the respective opposing surface 204, 206. In some of these embodiments, one or both of the surfaces 204, 206 may be electrically conductive electrodes. In others of these embodiments, one or both of the surfaces 204, 206 may comprise an electrode on the surface 204, 206. For example, one or both of the surfaces 204, 206 also may be an electrically conductive electrode material. FIG. 3A illustrates an example where the surfaces 204, 206 are electrically conductive and insulated from one another with an insulator layer 205 at an interface between the surfaces 204, 206. The nanoshell 210 may or may not be electrically conductive, depending on the embodiment. FIG. 3B illustrates an example where a respective opposing surface 206 comprises an electrode 207 in the gap 208 that is electrically insulated from the surfaces 204, 206 by an insulator layer 205. Other arrangements of electrically conductive surfaces and electrodes with respect to the nanoshell and the gap are within the scope of the embodiments herein.

In some embodiments, the detector 220 is a capacitive monitor that measures a capacitance across the gap 208. The detector 220 is connected at one end to electrically access the nanoshell 210 side of the gap 208 on the horizontal surface 206 and connected at another end to the opposing surface 204, wherein both surfaces of the substrate 202 function as electrodes (FIG. 3A, for example). In other embodiments, the capacitive detector 220 is connected to an electrode 207 on the opposing surface 206 and to the surface 204 to electrically access the nanoshell 210 side of the gap 208, as illustrated in FIG. 3B. Movement of the nanoshell 210 changes a size of the gap 208, which is measured capacitively with the detector 220 by way of the respective electrodes or electrically conductive surfaces.

In other embodiments, the means for detecting is a detector 220 that senses changes in an electromagnetic environment created using the nanoshell 210. For example, for a nanoshell resonator that is electrically contacted at both ends (not illustrated), a uniform magnetic field is created around the nanoshell and a current is passed through the nanoshell perpendicular to the magnetic field to cause the nanoshell to resonate in the applied magnetic field. The motion of the nanoshell generates an electromotive force in the gap. The electromotive force and changes in the electromotive force are sensed by the detector by way of the above-described respective electrodes.

In another example, the respective opposing surface 204, 206 may be a mirrored surface. In this example, the detector 220 is an optical interferometer that measures reflections from the nanoshell 210 and from the mirrored surface; changes in interference between the reflections from the two surfaces are caused by movement of the nanoshell 210 in the gap 208.

In some embodiments of the nanoscale sensor 200, the nanoshell 210 is connected to the respective surface 204, 206 without an epitaxial connection. In these embodiments, both the nanoshell 210 and the respective surface 204, 206 may independently comprise either a crystalline material or an amorphous material. In other embodiments, the nanoscale sensor 200 further comprises an epitaxial connection between the nanoshell 210 and the respective surface 204, 206. The epitaxial connection may be either a direct epitaxial connection or an indirect epitaxial connection between the nanoshell 210 and the respective surface 204, 206. In some embodiments, an indirect epitaxial connection may comprise a nanowire stub which facilitates the indirect epitaxial connection. In some embodiments, the nanoscale sensor 200 comprises any of the embodiments of the nanoscale apparatus 100 described above.

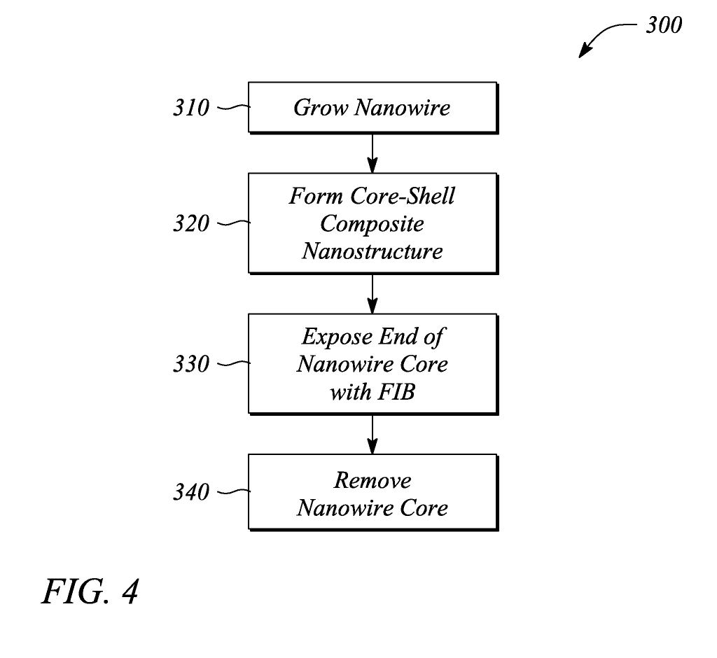

In some embodiments of the present invention, a method of making a nanoscale apparatus is provided. FIG. 4 illustrates a flow chart of a method 300 of making a nanoscale apparatus according to an embodiment of the present invention. The method 300 of making a nanoscale apparatus comprises growing 310 a nanowire on a surface. The surface may be a surface of a substrate or a surface of a wall or post on a substrate. A sacrificial, single crystal nanowire is grown 310 as a template from the surface such that one end of the nanowire is connected to the surface while the opposite end is free from the surface during growth. The connection between the nanowire end and the surface may be either epitaxial or non-epitaxial, depending on the embodiment. A single crystal nanowire can grow on the surface, whether the surface is an amorphous material, a single crystal material, a polycrystalline material or a microcrystalline material. The nanowire is grown using any of a variety of techniques. For example, a catalyzed growth technique includes, but is not limited to, metal-catalyzed growth using one of a vapor-liquid-solid (VLS) technique and a vapor-solid (VS) technique. The metal-catalyzed growth technique may use a nanoparticle catalyst.

In some embodiments, growing 310 a nanowire using catalyzed growth comprises selectively forming a nanoparticle catalyst on the surface using one or more techniques including, but not limited to, electron-beam evaporation, electrochemical deposition, deposition of preformed nanoparticles, and chemical vapor deposition, which deposits catalyst material on the surface. If the nanowire is grown on a vertical surface, angled deposition, such as with electron-beam evaporation, or deposition of preformed nanoparticles may be used to form the nanoparticle catalyst on the vertical surface. In some embodiments, selectively forming a nanoparticle catalyst further includes annealing the deposited catalyst material.

Typical catalyst materials are metals and nonmetals. Metal catalyst materials include, but are not limited to, gold (Au), titanium (Ti), platinum (Pt), nickel (Ni), aluminum (Al), tungsten (W), gallium (Ga), and alloys thereof. Typical nanoparticle catalysts corresponding to Ti and Au catalyst materials used with a silicon surface, for example, are respectively TiSi₂ and Au—Si alloy.

Nanowire growth 310 is initiated from a location on the surface where the nanoparticle catalyst was formed or deposited. For example, a substrate comprising the surface is placed in a chemical vapor deposition (CVD) chamber with a controlled environment. A combination of the nanoparticle catalyst and a gas mixture comprising precursor nanowire materials in the controlled environment facilitates catalyzed nanowire growth 310. The single crystal nanowire will grow 310 in place anchored to the surface from the location of the nanoparticle catalyst. The nanoparticle catalyst remains on the free end of the nanowire during and after growth 310.

The method 300 of making a nanoscale apparatus further comprises forming 320 a core-shell composite nanostructure using the nanowire as the core. In some embodiments, forming 320 a core-shell composite nanostructure comprises depositing a layer of a nanoshell material on the nanowire core to thoroughly (i.e., conformally) coat the nanowire core. In some embodiments, the layer of nanoshell material may be an epitaxial layer of the nanoshell material on the nanowire core. In some embodiments, the nanoshell material may be deposited non-catalytically using a CVD chamber, for example using the same CVD chamber used to grow 310 the nanowire core, and may be grown using different deposition conditions; for example, growing at a higher temperature than used for growing 310 the nanowire. In some of these embodiments, the layer of nanoshell material further deposits on the substrate surface surrounding a base of the nanowire core. In some embodiments, the epitaxial layer of the nanoshell material forms a direct epitaxial connection to the nanowire core and in some embodiments, also to the substrate surface surrounding the base of the nanowire core. In other embodiments, the deposition of the nanoshell material on one or both of the nanowire core and the substrate surface either is not an epitaxial layer or does not create a direct epitaxial connection.

In other embodiments, forming 320 a core-shell composite nanostructure comprises forming a nanoshell from the nanowire, for example using a growth process. For example, a growth process that grows an oxide or a nitride of the nanowire material to cover the nanowire core and that may consume some of the nanowire core. According to some of these embodiments, the nanoshell is amorphous and does not form an epitaxial connection to either the nanowire core or the substrate during the nanoshell growth process, but does form strong bonds to both.

The method 300 of making a nanoscale apparatus further comprises exposing 330 an end of the nanowire core of the core-shell composite nanostructure that is opposite to the substrate. Exposing 330 an end comprises removing a portion of the nanoshell from the end of the core-shell composite nanostructure to expose the nanowire core.

In some embodiments, a focused ion beam (FIB) is used to remove the portion of the nanoshell. In some embodiments, the focused ion beam further removes the nanoparticle catalyst at the end of the nanowire core, and may also expose a portion of the nanowire core. In some embodiments, the FIB technique uses accelerated ions including, but not limited to, gallium ions, argon ions, or krypton ions, for example, from an ion gun to penetrate or cut a material to be removed. As a result of using the focused ion beam, the nanowire core is exposed 330 and accessible at the end of the composite nanostructure. Using a focused ion beam to expose the nanowire core end is particularly useful when the composite nanostructure extends laterally from a vertical surface, similar to that illustrated for the nanoscale apparatus 100 in FIG. 1B.

In other embodiments, other techniques for exposing 330 an end of the nanowire core may be used. For example, the core-shell composite nanostructure may be vertically oriented similar to the nanoscale apparatus 100 that is illustrated in FIG. 1A. In this example, a filling material is applied to surround the core-shell composite nanostructure. The filling material is different from the materials of the core-shell composite nanostructure. For example a silicon oxide material or a polymer material may be used. After the filling material is applied, chemical-mechanical polishing (CMP) is used to remove the top portion of the filling material and the free end of the core-shell composite nanostructure. Removing the top portion using CMP exposes 330 the end of the nanowire core to make it accessible. The filling material may be subsequently removed using an etching technique at any time after the nanowire core is exposed 330.

The method 300 of making further comprises removing 340 the nanowire core from the core-shell composite nanostructure such that the nanoshell having a hollow region remains attached to the substrate. Removing 340 the nanowire core relies on different materials being used for the nanowire core and the nanoshell. The different materials are chemically different in that one of the materials is selectively removable without much effect on the other material. For example, germanium (Ge) and silicon (Si) are different Group IV semiconductor materials that have selective etchants. Hydrogen peroxide will remove Ge but not remove Si. In this example, if the nanowire core is Ge and the nanoshell is Si, wet etching the exposed Ge nanowire core with a solution comprising hydrogen peroxide will remove a targeted amount of the Ge core from the composite nanostructure and will leave the Si nanoshell with a hollow region along an axial length of the nanoshell.

In some embodiments, removing 340 the nanowire core comprises removing most of the nanowire core material from the core-shell composite nanostructure. By ‘most’ it is meant that remnants of the nanowire material might be left in a hollow region of the nanoshell, for example. In some embodiments, removing 340 the nanowire core comprises deliberately leaving a nanowire stub at an interface with the surface. In some embodiments, the single crystal nanowire stub facilitates an indirect epitaxial connection between the nanoshell and the surface, for example when an end of the nanoshell is adjacent to but physically spaced from the surface. In another example, an amorphous nanoshell may be indirectly epitaxially connected to a crystalline surface using the nanowire stub. In this example, the nanowire stub is directly epitaxially connected to the surface at a base of the nanowire stub and is connected to the amorphous nanoshell at an axial end portion of the nanowire stub that is opposite to the base. The amorphous nanoshell overlaps the axial end portion of the nanowire stub, for example, as illustrated in FIG. 2B, for example. In effect, the nanoshell is indirectly epitaxially connected to the surface by way of the nanowire stub.

In some embodiments, the method 300 of making a nanoscale apparatus is used to make the nanoscale apparatus 100 according to any of the embodiments described herein. In some embodiments, the method 300 of making a nanoscale apparatus is used to make the nanoscale sensor 200 according to any of the embodiments described herein. In some of these embodiments, the method 300 of making a nanoscale sensor further comprises forming a post on a substrate or from a substrate, such that the substrate comprises a relatively vertical surface adjacent to a relatively horizontal surface (i.e., relatively perpendicular extending surfaces). The post may be formed using one or more of photolithography and nanoimprint lithography (NIL) followed by etching, for example. Moreover, growing 310 a nanowire comprises growing the nanowire from either the relatively vertical surface or the relatively horizontal surface. In some embodiments, making the nanoscale sensor further comprises rendering a surface of one or both of the post and the substrate electrically conductive; and connecting a detector to the post and the substrate, for example.

Thus, there have been described various embodiments of a nanoscale apparatus, a nanoscale sensor and a method of making that employ a nanoshell. It should be understood that the above-described embodiments are merely illustrative of some of the many specific embodiments that represent the principles of the present invention. Clearly, other arrangements can be readily devised without departing from the scope of the present invention as defined by the following claims.

What is claimed is:

1. A nanoscale apparatus (100) comprising:
a nanoshell (110) of a material that excludes sp²-bonded carbon materials, the nanoshell (110) extending from a substrate (102); and
an epitaxial connection (120) between the substrate (102) and an end (112) of the nanoshell (110) adjacent to the substrate.

2. The nanoscale apparatus (100) of claim 1, wherein the nanoshell (110) is a crystalline material, the substrate (102) comprising a crystalline surface, the epitaxial connection (120) comprising a direct epitaxial connection between the crystalline surface of the substrate (102) and the end (112) of the crystalline nanoshell (110).

3. The nanoscale apparatus (100) of claim 2, wherein the direct epitaxial connection (120) further comprises a layer (113) of the material of the crystalline nanoshell (110) on the crystalline surface of the substrate (102), the layer (113) being continuous with and surrounding a base of the crystalline nanoshell (110).

4. The nanoscale apparatus (100) of claim 1, wherein the epitaxial connection (120) is an indirect connection between the substrate (102) and the end (112) of the nanoshell (110).

5. The nanoscale apparatus (100) of claim 4, wherein the indirect epitaxial connection (120) comprises a nanowire stub (130) connected between the substrate (102) and the nanoshell (110), the substrate (102) comprising a crystalline surface, the nanowire stub (130) being directly epitaxially connected to the crystalline surface of the substrate (102), the nanoshell (110) being connected to the nanowire stub (130), such that the end (112) of the nanoshell (110) is spaced from and indirectly epitaxially connected to the substrate (102) by way of the nanowire stub (130).

6. The nanoscale apparatus (100) of claim 4, wherein the indirect epitaxial connection comprises a nanowire stub (130) connected between the substrate (102) and the nanoshell (110), the nanoshell (110) being a crystalline material, the crystalline nanoshell (110) being directly epitaxially connected to the nanowire stub (130), the nanowire stub (130) being connected to the substrate (102), such that the end (112) of the crystalline nanoshell (110) is spaced from and indirectly epitaxially connected to the substrate (102) by way of the nanowire stub (130).

7. The nanoscale apparatus (100) of claim 1, wherein the substrate (102) comprises one or both of a crystalline material and an amorphous material, one or both of the nanoshell (110) and a surface of the substrate (102) is independently a single crystal material, the surface being adjacent to the end (112) of the nanoshell (110).

8. The nanoscale apparatus (100) of claim 1, wherein the nanoshell (110) comprises a functionalized surface to interact with a stimulus.

9. A nanoscale sensor (200) comprising the nanoscale apparatus (100) of claim 1, the nanoscale sensor further comprising a detector that monitors movement of the nanoshell (110), the detector monitoring the nanoshell (110) relative to a wall extending from the substrate (102) that is adjacent to and spaced from the nanoshell (110) by a gap.

10. A nanoscale sensor (200) comprising:
surfaces (204, 206) that extend relatively perpendicular to each other;
a nanoshell (210) of a material that excludes sp²-bonded carbon materials, the nanoshell (210) extending from a first one of the surfaces (204, 206), the nanoshell (210) being spaced from a second one of the surfaces (204, 206) by a gap (208); and
a detector (220) that monitors motion of the nanoshell (210) relative to the second surface.

11. The nanoscale sensor (200) of claim 10, wherein the detector (220) monitors motion one of capacitively and electromagnetically, one or both of the surfaces (204, 206) comprising an electrode.

12. The nanoscale sensor (200) of claim 10, further comprising an epitaxial connection between the nanoshell (210) and the first surface, the epitaxial connection being either a direct connection or an indirect connection, one or both of the nanoshell (210) and the first surface being a crystalline material.

13. The nanoscale sensor (200) of claim 10, further comprising an indirect epitaxial connection between the nanoshell (210) and the first surface, the indirect epitaxial connection comprising a nanowire stub (130) connected between the first surface and the nanoshell (210), the nanowire stub (130) being directly epitaxially connected to one or both of the first surface and the nanoshell (210).

14. A method (300) of making a nanoscale apparatus comprising:
growing (310) a nanowire on a surface;
forming (320) a core-shell composite nanostructure with the nanowire as a core and a shell material that excludes sp²-bonded carbon materials surrounding the nanowire core;
exposing (330) an end of the nanowire core of the core-shell composite nanostructure opposite to the surface with a focused ion beam; and
removing (340) the nanowire core from the exposed end, such that a nanoshell having a hollow region is attached to the surface.

15. The method (300) of making of claim 14, wherein forming (320) a core-shell composite nanostructure comprises depositing the shell material on the nanowire core, and wherein the nanoshell is either indirectly epitaxially connected to the surface using a stub of the nanowire core that remains after removing (340) or directly epitaxially connected to the surface.
